(19) United States
(12) Patent Application Publication
(10) Pub. No.: US 2013/0070793 A1
(43) Pub. Date: Mar. 21, 2013

(54) FIBER LASER

(71) Applicant: Isshu SASAKI, Kanagawa-ken (JP)

(72) Inventor: Isshu SASAKI, Kanagawa-ken (JP)

(73) Assignee: Kabushiki Kaisha Toshiba, Tokyo (JP)

(21) Appl. No.: 13/616,764

(22) Filed: Sep. 14, 2012

(30) Foreign Application Priority Data
Sep. 16, 2011 (JP) 2011-203707

(51) Int. Cl. H01S 3/067; H01S 5/02

(52) U.S. Cl. 372/6

(57) ABSTRACT

A fiber laser includes: a seed light source; a preamplifier unit including a first optical fiber doped with a first rare earth element and amplifying a pulse seed light; a main amplifier unit including a second optical fiber doped with a second rare earth element and the first rare earth element and further amplifying light amplified by the preamplifier unit; and a buffer optical fiber provided between the preamplifier unit and the main amplifier unit, and doped with the second rare earth element. Amplified spontaneous emission light emitted by energy stored in the second rare earth element and the second excitation light not absorbed into the first and second rare earth elements of the second optical fiber but remaining are absorbed into the second rare earth element of the buffer optical fiber.

### CROSS-REFERENCE TO RELATED APPLICATIONS

This application is based upon and claims the benefit of priority from the prior Japanese Patent Application No. 2011-203707, filed on Sep. 16, 2011; the entire contents of which are incorporated herein by reference.

### FIELD

Embodiments described herein relate generally to a fiber laser.

### BACKGROUND

In an infra-red sensor and a laser processing apparatus, high-power pulse laser light is required. Hence, in many cases, pulse seed light from a semiconductor laser is amplified by a fiber laser amplifier to obtain high-power pulse laser light.

In the fiber laser amplifier, a rare earth element dispersed in the core absorbs excitation light, and amplifies the pulse seed light by stimulated emission.

Thermal damage may be caused in the vicinity of the fusion splice of the optical fiber or in optical parts by excitation light not absorbed into the rare earth element but propagated through the optical fiber or by amplified spontaneous emission (ASE) light.

### BRIEF DESCRIPTION OF THE DRAWINGS

FIG. 1A is a configuration view of a fiber laser of a first embodiment, and FIG. 1B is a schematic cross-sectional view of a double-clad fiber along line A-A;

FIG. 2A is a graph showing an emission and an absorption spectrum of Er, and FIG. 2B is a graph showing an emission and an absorption spectrum of Yb;

FIG. 3A is a waveform diagram of the pulse seed light from the seed light source, and FIG. 3B is a waveform diagram of the light pulse at the first end of the second optical fiber; and

FIG. 4 is a configuration view of a fiber laser according to a comparative example.

### DETAILED DESCRIPTION

In general, according to one embodiment, a fiber laser includes: a seed light source capable of emitting pulse seed light; a preamplifier unit including a first optical fiber having a core doped with a first rare earth element, the first rare earth element being excited by absorbing first excitation light and amplifying the pulse seed light; a main amplifier unit including a second optical fiber having a core doped with a second rare earth element and the first rare earth element, and a double-clad structure, the first and second rare earth elements being excited by absorbing the second excitation light, further amplifying light amplified by the preamplifier unit and outputting outward; and a buffer optical fiber provided between the preamplifier unit and the main amplifier unit, and having a core doped with the second rare earth element and a double-clad structure. Amplified spontaneous emission light emitted by energy stored in the second rare earth element in the second optical fiber and the second excitation light not absorbed into the first and second rare earth elements of the second optical fiber but remaining are absorbed into the second rare earth element of the buffer optical fiber.

Various embodiments will be described hereinafter with reference to the accompanying drawings.

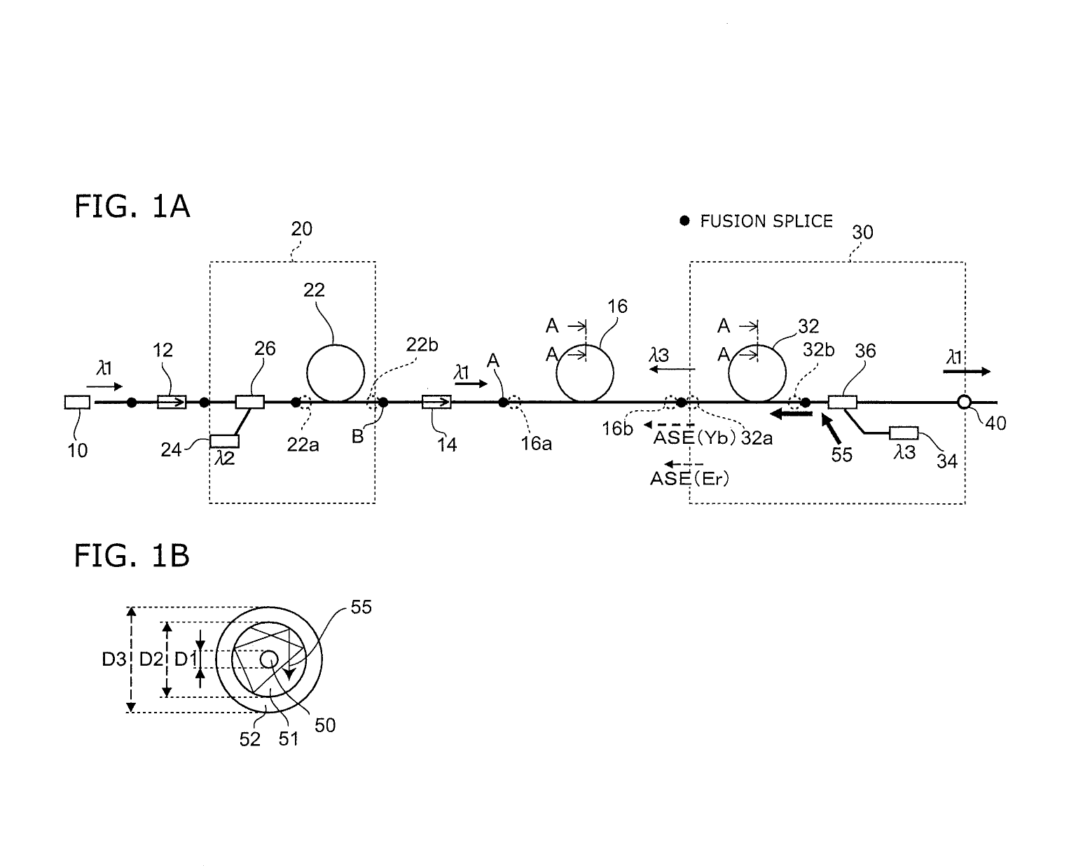

FIG. 1A is a configuration view of a fiber laser of a first embodiment, and FIG. 1B is a schematic cross-sectional view of a double-clad fiber along line A-A.

The fiber laser includes a seed light source 10, a preamplifier unit 20, a buffer optical fiber 16, and a main amplifier unit 30. In the drawing, the black circle mark indicates the fusion splice of the fiber.

The seed light source 10 emits pulse seed light with a light emission wavelength of λ1. When a semiconductor laser element made of InGaAsP or the like is used as the seed light source 10, the light emission wavelength λ1 can be made near 1.56 μm. Using a DFB (distributed feed back) structure for the semiconductor laser element can provide a narrow emission spectrum line width.

The preamplifier unit 20 includes a first optical fiber 22 having a core doped with a first rare earth element and a first excitation light source 24 capable of emitting first excitation light capable of exciting the first rare earth element. The first optical fiber 22 has a first end 22a on the seed light source 10 side and a second end 22b on an opposite side of the first end 22a. The first excitation light is usually a CW (continuous wave), and continuously excites the first rare earth element.

When the preamplifier unit 20 further includes a WDM (wavelength division multiplexing) coupler 26 on the first end 22a side, the first excitation light can be injected into the first optical fiber 22 with high coupling efficiency. The first excitation light source 24 may be a high-power module using semiconductor laser elements of AlGaAs or the like. Since the excitation light intensity in the preamplifier unit 20 may be set lower than that in the main amplifier unit 30, the first optical fiber 22 may be configured to be a single-clad fiber.

A first optical isolator 12 is provided between the seed light source 10 and the WDM coupler 26. The optical isolator can transmit light of a specific wavelength substantially only in one direction by means of a Faraday rotator made of a magneto-optical material. Thus, the first optical isolator 12 can suppress the return light of the pulse seed light returning to the seed light source 10, and the seed light source 10 can operate stably. Furthermore, a second optical isolator 14 can suppress optical components near the wavelength λ1 being incident on the second end 22b of the first optical fiber 22.

The optical fiber used for the seed light source 10, the first optical isolator 12, the second optical isolator 14, and the WDM coupler 26 may be a single-mode fiber of a single-clad structure. Since the first excitation light may be low power, the portion between the first excitation light source 24 and the WDM coupler 26 may be configured to be a single-mode single-clad fiber with a small fiber diameter.

The main amplifier unit 30 includes a second optical fiber 32 having a core doped with a first and a second rare earth element and a second excitation light source 34 capable of emitting second excitation light capable of exciting the first and second rare earth elements. The second optical fiber 32 has a first end 32a on the preamplifier unit 20 side and a second end 32b on an opposite side of the first end 32a, and has a double-clad structure. The second excitation light is usually a CW (continuous wave), and continuously excites the second rare earth element.

As shown in FIG. 1B, the double-clad structure includes a core 50, an inner cladding 51 surrounding the core 50, and an outer cladding 52 surrounding the inner cladding 51. The inner cladding 51 functions as a cladding for the pulse seed light, and the pulse seed light propagates through the core 50. The outer cladding 52 functions as a cladding for excitation light 55, and the excitation light prooagates through the inner cladding 51 and the core 50.

When the main amplifier unit 30 further includes a combiner 36 or the like, the second excitation light can be injected into the inner cladding of the second optical fiber 32 with high coupling efficiency. In this case, when the combiner 36 is provided on the second end 32b side of the second optical fiber 32, excitation energy can be increased on the emission end side to facilitate emitting high-power pulse laser light.

That is, since the excitation light injected from the second end 32b is absorbed into the second rare earth element, light intensity decreases with propagation (with proximity to the first end 32a).

Thus, by injecting the second excitation light from the second end 32b, a maximum amplification gain can be obtained at the output end 40 of the second optical fiber 32.

The buffer optical fiber 16 is provided between the preamplifier unit 20 and the main amplifier unit 30, and its core is doped with the second rare earth element. Connection loss can be reduced by configuring the buffer optical fiber 16 in a single-mode double-clad structure and fusing it with the second optical fiber 32 that is a single-mode double-clad structure with good alignment.

The buffer optical fiber 16 has a first end 16a on the preamplifier unit 20 side and a second end 16b on the main amplifier unit 30 side.

The second excitation light that has not been absorbed into the first and second rare earth elements introduced in the second optical fiber 32 but remains is incident on the second end 16b of the buffer optical fiber 16, and is propagated through its core and inner cladding. Also the ASE light generated in the second optical fiber 32 is incident on the second end 16b of the buffer optical fiber 16.

In the following description, the wavelength λ1 of the pulse seed light is assumed to be 1.55 μm. The first optical fiber 22 is assumed to be a single-clad structure doped with erbium (Er) as the first rare earth element. The second optical fiber 32 is assumed to be a double-clad structure doped with Er as the first rare earth element and ytterbium (Yb) as the second rare earth element. Furthermore, the buffer optical fiber 16 is assumed to be a double-clad structure doped with Yb that is the second rare earth element in its core. The wavelength λ1 of the pulse seed light, the material of the first and second rare earth elements, etc. are not limited to these.

The preamplifier unit 20 may be referred to as an Er-doped optical fiber amplifier (EDFA). The main amplifier unit 30 may be referred to as an Er/Yb-doped optical fiber amplifier (EYDFA).

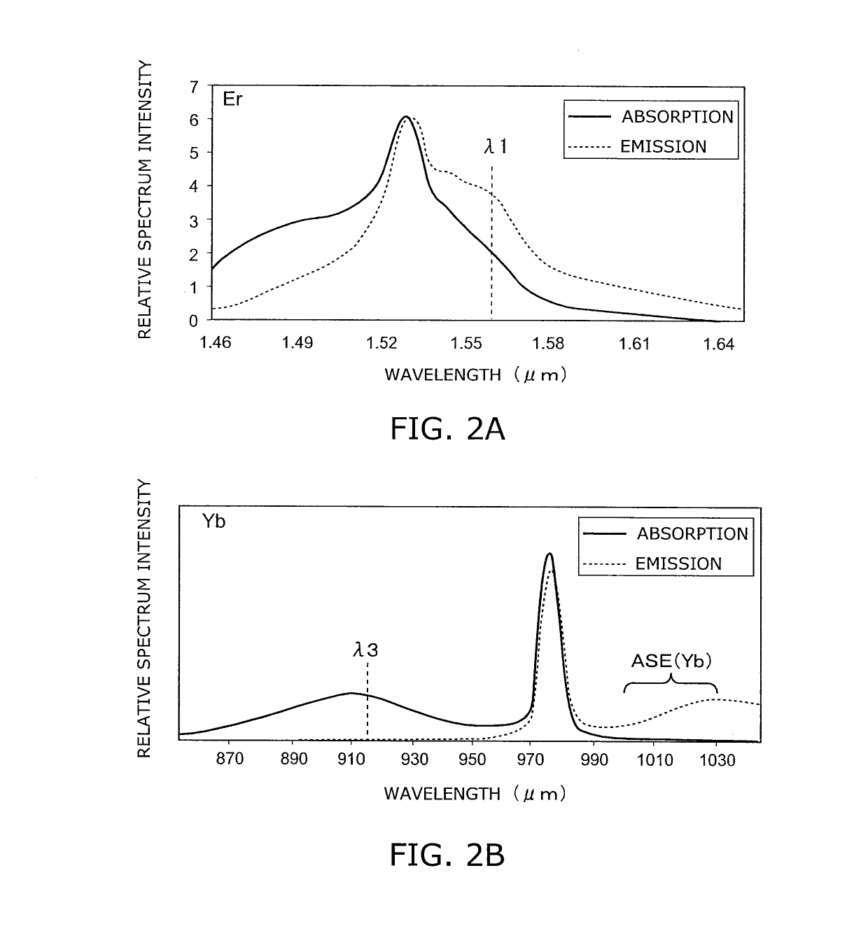

FIG. 2A is a graph showing an emission and an absorption spectrum of Er, and FIG. 2B is a graph showing an emission and an absorption spectrum of Yb.

As shown in FIG. 2A, for Er, the maximum value of the light emission intensity and the maximum value of the absorption intensity are close to each other in the neighborhood of 1.53 μm. That is, self absorption is large. For Er, λ1 which is the wavelength of the pulse seed light is set to near 1.55 μm which is longer than 1.53 μm. Thereby, the rate of decrease from the maximum value in the light emission intensity can be made smaller than the rate of decrease from the maximum value in the absorption intensity. As a consequence, the effective amplification gain can be increased to facilitate amplifying the pulse seed light. When the wavelength λ2 of the first excitation light is set to 0.975 μm or 1.44 μm, Er can amplify the pulse seed light of 1.55 μm with high efficiency. The energy stored in Er can emit ASE light with a wide wavelength range of 1.53 to 1.70 μm.

As shown in FIG. 2B, the absorption intensity of Yb reaches a maximum when the wavelength λ3 of the excitation light is near 0.975 μm. There is also high absorption intensity at 0.915 μm. The light emission intensity of Yb reaches a maximum when the wavelength λ3 of the excitation light is near 1.03 μm. Therefore, Yb can emit ASE light with a wide wavelength range of 1.0 to 1.1 μm.

In the case where high excitation power is needed to obtain the higher pulse laser power with a wavelength of near 1.55 μm, a double-clad fiber may be sometimes used. A rare earth element is doped in the core, but not doped in the inner cladding. Since the excitation light propagates through the inner cladding, the absorptance of the excitation light is low as compared to propagation through the core. In order to obtain greater absorption, the concentration of the rare earth element can be increased in the core. However, if the concentration of the Er element is increased, also self absorption increases, and this causes an amplification efficiency decrease. Hence, by co-doping with the Yb element and the Er element and increasing the concentration of the Yb element, self absorption can be suppressed and the absorption of the excitation light can be increased. In this case, Yb excited by a wavelength near 0.915 μm or 0.980 μm emits ASE light with a wide wavelength range of 1.0 to 1.1 μm, and brings about an energy transition in Er. A population inversion is created between the levels caused by the energy transition, the pulse seed light with a wavelength of 1.55 82 m is amplified with high efficiency, and high-power pulse laser light is emitted from the output end 40.

The concentration of Er and Yb introduced may be, for example, 2000 to 20,000 ppm or the like.

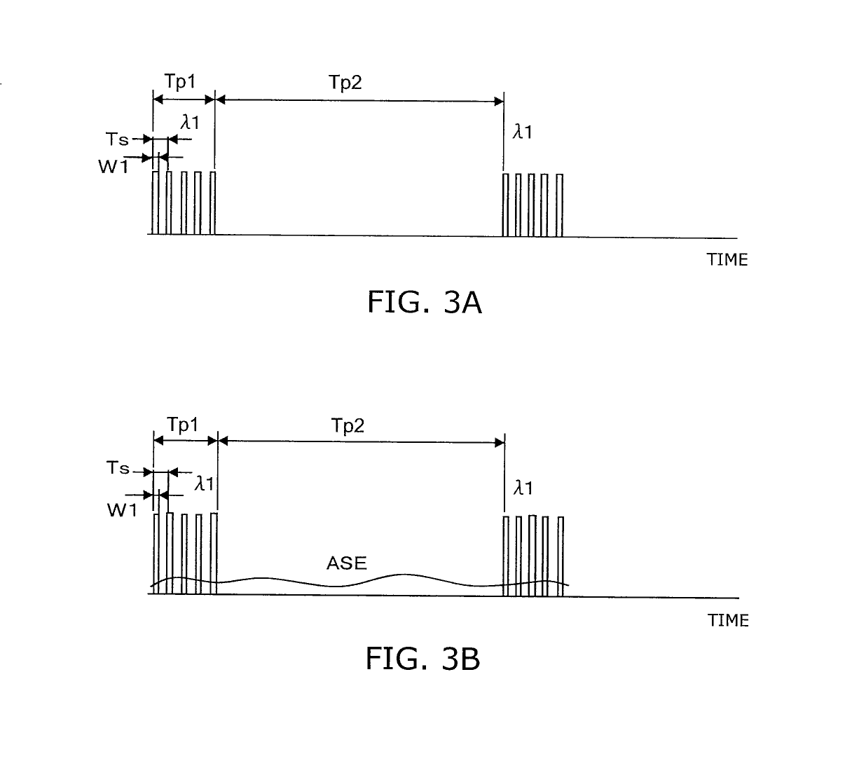

FIG. 3A is a waveform diagram of the pulse seed light from the seed light source, and FIG. 3B is a waveform diagram of the light pulse at the first end of the second optical fiber.

The pulse seed light has an emission period Tp1 in which a pulse train of seed light (wavelength λ1) with a period of Ts is emitted and a non-emission period Tp2 in which no pulse train is emitted. The period Ts may be, for example, between 50 μs (corresponding to the repetition frequency being 20 kHz) and 100 μs (corresponding to the repetition frequency being 10 kHz). The period Ts is not limited to this range. When the period Ts is 50 μs, the pulse width W1 may be 10 to 100 nm or the like. In this case, W1/Ts is as low as 0.2 to 2%.

As shown in FIG. 3B, in the second optical fiber 32 in the emission period Tp1 of the pulse seed light, the pulse seed light that has passed through the buffer optical fiber 16 is amplified. The ASE light of Yb is incident from the first end 32a on the second end 16b of the buffer optical fiber 16 in both the periods Tp1 and Tp2. The ASE light of Er is incident on the second end 16b of the buffer optical fiber 16. The ASE light is continuously emitted for a sufficiently long period with respect to the pulse width W1, and is therefore nearly CW light.

The second excitation light not absorbed in the second optical fiber 32 propagates through the inner cladding of the second optical fiber 32 and emitted from the first end 32a of the second optical fiber 32. The ASE light by Yb and Er is emitted from the first end 32a of the second optical fiber 32.

The buffer optical fiber 16 doped with Yb in its core is configured to have such a length as to sufficiently absorb the

ASE light of Yb and the second excitation light emitted from the first end 32a of the second optical fiber 32. In the embodiment, the second excitation light and the ASE light are caused to be incident on the second end 16b of the buffer optical fiber 16 to be sufficiently absorbed into Yb in the buffer optical fiber 16. That is, of the second excitation light and the ASE light shown in FIG. 3B, the ASE light of Yb is attenuated in the buffer optical fiber 16.

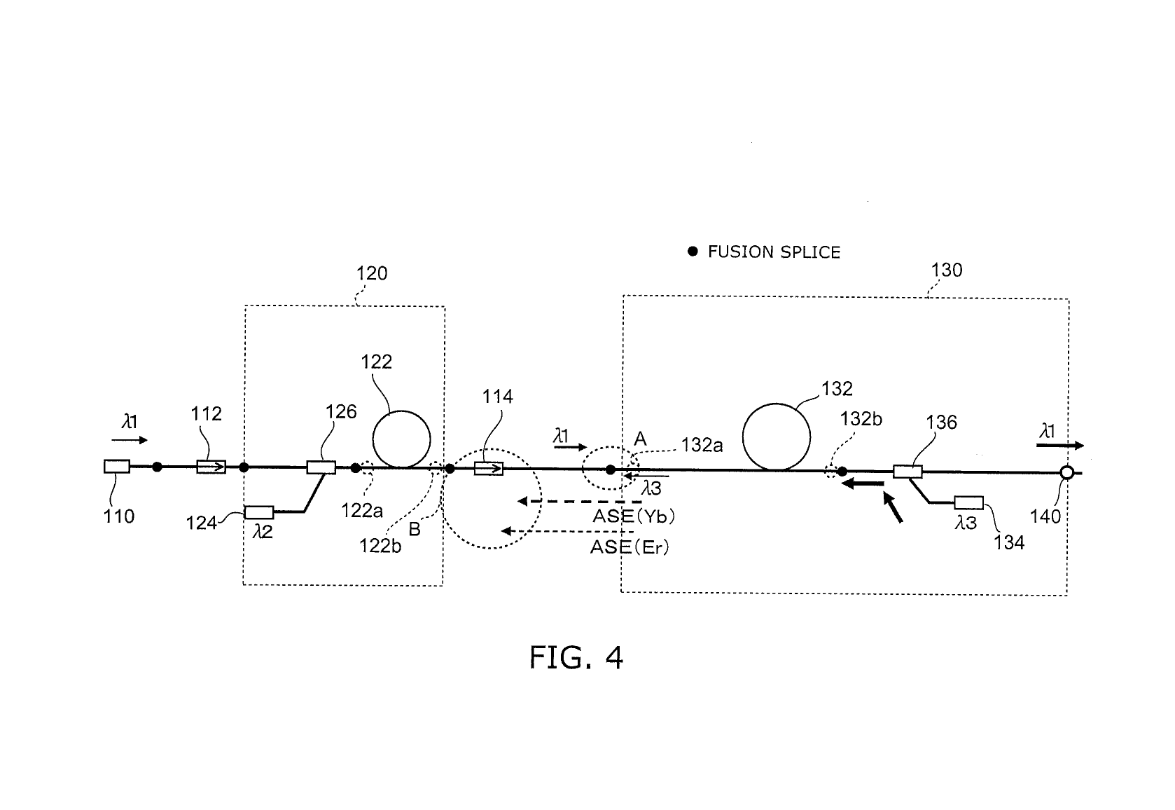

FIG. 4 is a configuration view of a fiber laser according to a comparative example.

The fiber laser includes a seed light source 110, a preamplifier unit 120, and a main amplifier unit 130. The black circle mark indicates the fusion splice of the optical fiber.

The seed light source 110 emits pulse seed light with a light emission wavelength λ1 of 1.55 μm. The preamplifier unit 120 includes a first optical fiber 122 doped with Er in its core and a first excitation light source 124 capable of emitting first excitation light capable of exciting Er. The first optical fiber 122 has a first end 122a on the seed light source 110 side and a second end 122b on the opposite side of the first end 122a.

The main amplifier unit 130 includes a second excitation light source 134 capable of emitting second excitation light capable of exciting Yb. A second optical fiber 132 has a first end 132a on the preamplifier unit 120 side and a second end 132b on the opposite side of the first end 132a, and has a double-clad structure.

A second optical isolator 114 is provided between the first optical fiber 122 and the second optical fiber 132. The second optical isolator 114 can suppress incidence of the ASE light of Er generated in the second optical fiber 132 on the first optical fiber 122.

The second excitation light is injected into the inner cladding from the second end 132b of the second optical fiber 132. A part of the second excitation light is absorbed into Yb doped in the core, but the other part of the second excitation light is not absorbed and propagates from the first end 132a toward a fusion splice A. A single-mode single-clad fiber is attached to the output side of the second optical isolator 114. On the other hand, the second optical fiber 132 is a single-mode double-clad fiber. In this case, when the second excitation light is high power, the inner cladding diameter is usually large. Thus, the diameters of the fibers are discontinuous in the cross section at the fusion splice A.

The part of the second excitation light not absorbed in the core diverges from the inner cladding to the outside, and is applied to the vicinity of the fusion splice A (the region of the broken line) to generate heat locally. The second excitation light is usually CW light, and has high energy. Therefore, for example, the coating etc. of the optical fiber may catch fire due to the diverging light. If the intensity of the diverging light is high, breaking of the optical fiber may occur.

The ASE light by Yb has an emission spectrum with a wide wavelength range of 1.0 to 1.1 μm. The ASE light is emitted from the core doped with Yb, is incident on the vicinity of the core of the single-mode single-clad fiber, and propagates through the optical fibers to reach the seed light source 110 and the first excitation light source 124. If the intensity of the ASE light is high, damage may be caused to these optical parts.

In order to reduce thermal damage to the fusion splice A due to the second excitation light, a structure may be employed in which a Peltier element or the like is provided to cool the heat generation region forcedly. However, the structure of the cooling unit is large, and this leads to a large-sized fiber laser. Furthermore, the power consumption of the Peltier element is high.

In contrast, the fiber laser of the embodiment shown in FIG. 1 includes the buffer optical fiber 16. The core of the buffer optical fiber 16 is doped with Yb. Therefore, the buffer optical fiber 16 has high absorption intensities at 0.915 μm and 0.975 μm that are the wavelengths of the second excitation light, and the light intensity at the fusion splice A is sufficiently reduced. In this case, Yb in the core generates heat due to the second excitation light propagated through the inner cladding. However, since the heat generation is divergent in the length direction of the buffer optical fiber 16, local heat concentration can be suppressed.

On the other hand, since the ASE light having an emission spectrum with a wide wavelength range of 1.0 to 1.1 μm is absorbed into Yb of the core of the buffer optical fiber 16, the intensity of the ASE light reaching the second optical isolator 14 can be reduced. That is, the light intensity can be reduced to such a level as not to cause damage to the seed light source 10 and the first excitation light source 24. Although the absorption intensity of Yb in the wavelength range of 1.0 to 1.1 μm is not high as shown in FIG. 2B, the quantity of light absorption can be increased by lengthening the buffer optical fiber 16.

Thus, thermal damage to the fusion splice A and optical parts can be reduced. Therefore, a cooling device using a Peltier element or the like is not needed, and a fiber laser with a small size and low power consumption can be provided. Such a fiber laser can be widely used for infra-red sensor, laser processing apparatus, etc.

While certain embodiments have been described, these embodiments have been presented by way of example only, and are not intended to limit the scope of the inventions. Indeed, the novel embodiments described herein may be embodied in a variety of other forms; further more, various omissions, substitutions and changes in the form of the embodiments described herein may be made without departing from the spirit of the inventions. The accompanying claims and their equivalents are intended to cover such forms or modification as would fail within the scope and spirit of the invention.

What is claimed is:

1. A fiber laser comprising:
a seed light source capable of emitting pulse seed light;
a preamplifier unit including a first optical fiber having a core doped with a first rare earth element, the first rare earth element being excited by absorbing first excitation light and amplifying the pulse seed light;
a main amplifier unit including a second optical fiber having a core doped with a second rare earth element and the first rare earth element, and a double-clad structure, the first and second rare earth elements being excited by absorbing the second excitation light, further amplifying light amplified by the preamplifier unit and outputting outward; and
a buffer optical fiber provided between the preamplifier unit and the main amplifier unit, and having a core doped with the second rare earth element and a double-clad structure,
amplified spontaneous emission light emitted by energy stored in the second rare earth element in the second optical fiber and the second excitation light not absorbed into the first and second rare earth elements of the second optical fiber but remaining being absorbed into the second rare earth element of the buffer optical fiber.

2. The fiber laser according to claim 1, wherein
the second optical fiber has a first end connected to the buffer optical fiber and a second end on an opposite side of the first end and
the second excitation light is injected from the second end side.

3. The fiber laser according to claim 1, wherein
the first rare earth element is Er and
the second rare earth element is Yb.

4. The fiber laser according to claim 3, wherein Yb doped in the core of the second optical fiber brings about an energy transition in Er to create a population inversion.

5. The fiber laser according to claim 1, wherein the seed light source includes semiconductor laser elements made of InGaAsP.

6. The fiber laser according to claim 5, wherein a wavelength of the pulse seed light emitted from the semiconductor laser elements is longer than 1.53 μm.

7. The fiber laser according to claim 6, wherein the semiconductor laser elements have distributed feed back structures.

8. The fiber laser according to claim 1, further comprising:
a first optical isolator provided between the seed light source and the first optical fiber.

9. The fiber laser according to claim 8, further comprising:
a second optical isolator provided between the preamplifier unit and the buffer optical fiber.

10. A fiber laser comprising:
a seed light source capable of emitting pulse seed light;
a preamplifier unit including a first optical fiber having a core doped with a first rare earth element, and a first wavelength division multiplexing coupler provided between the seed light source and the first optical fiber, the first rare earth element being excited by absorbing first excitation light introduced via the first wavelength division multiplexing coupler and amplifying the pulse seed light;
a main amplifier unit including a second optical fiber having a core doped with a second rare earth element and the first rare earth element, and a second wavelength division multiplexing coupler provided on an output end side of the second optical fiber, the first and second rare earth elements being excited by absorbing second excitation light introduced via the second wavelength division multiplexing coupler, further amplifying light amplified by the preamplifier unit and outputting outward; and
a buffer optical fiber provided between the preamplifier unit and the main amplifier unit and having a core doped with the second rare earth element and a double-clad structure,
amplified spontaneous emission light emitted by energy stored in the second rare earth element in the second optical fiber and the second excitation light not absorbed into the first and second rare earth elements of the second optical fiber but remaining being absorbed into the second rare earth element of the buffer optical fiber.

11. The fiber laser according to claim 10, wherein
the first rare earth element is Er and
the second rare earth element is Yb.

12. The fiber laser according to claim 11, wherein Yb doped in the core of the second optical fiber brings about an energy transition in Er to create a population inversion.

13. The fiber laser according to claim 10, wherein the seed light source includes semiconductor laser elements made of InGaAsP.

14. The fiber laser according to claim 10, wherein a wavelength of the pulse seed light emitted from the semiconductor laser elements is longer than 1.53 μm.

15. The fiber laser according to claim 14, wherein the semiconductor laser elements have distributed feed back structures.

16. The fiber laser according to claim 10, further comprising:
a first optical isolator provided between the seed light source and the first wavelength division multiplexing coupler.

17. The fiber laser according to claim 10, further comprising:
a second optical isolator provided between the preamplifier unit and the buffer optical fiber.
